(19) United States
(12) Patent Application Publication
(10) Pub. No.: US 2024/0393065 A1
(43) Pub. Date: Nov. 28, 2024

(54) HEAT DISSIPATION STRUCTURE

(71) Applicant: LEOTEK CORPORATION, Taipei City (TW)

(72) Inventor: Lu Yu Chiang, Taipei City (TW)

(73) Assignee: LEOTEK CORPORATION, Taipei City (TW)

(21) Appl. No.: 18/366,570

(22) Filed: Aug. 7, 2023

(30) Foreign Application Priority Data
May 24, 2023 (TW) 112119225

(51) Int. Cl. F28F 3/12

(52) U.S. Cl. CPC F28F 3/12; F28D 2021/0029; F28F 2215/00

(57) ABSTRACT

A heat dissipation structure adapted to dissipate heat from a heat generating component includes a central housing and a first wing housing. The central housing includes a top portion and a bottom portion opposite to each other, an internal space located between the top portion and the bottom portion, and a first opening communicating with the internal space. The top portion includes multiple through holes. The bottom portion is connected to the heat generating component. The first wing housing is connected to the central housing and includes a first entrance distant from the central housing and communicating with the first opening. The first entrance has a dimension larger than the first opening. An air flow sequentially flows through the first entrance, the first opening, and the internal space and flows out from the through holes.

### CROSS-REFERENCE TO RELATED APPLICATION

This application claims the priority benefit of Taiwan application serial no. 112119225, filed on May 24, 2023. The entirety of the above-mentioned patent application is hereby incorporated by reference herein and made a part of this specification.

### BACKGROUND

### Technical Field

The disclosure relates to a heat dissipation structure, and in particular to a heat dissipation structure having a good heat dissipation effect.

### Description of Related Art

Generally, the temperature of an electronic device with a light-emitting element (such as a street lamp) increases with time of operation. In order to reduce the temperature of the device, it is common to connect heat dissipation fins to the light-emitting element so that the heat generated by the light-emitting element can be dissipated into the air through the surface of the fins. However, this heat dissipation method relies on the structure and material of the heat dissipation fins, and has limited heat dissipation effect. Moreover, the heat dissipation fins are usually heavy due to their structure, which is disadvantageous in reducing the weight of the device.

### SUMMARY

The disclosure provides a heat dissipation structure to improve the heat dissipation effect.

A heat dissipation structure of the disclosure is adapted to dissipate heat from a heat generating component, and includes a central housing and a first wing housing. The central housing includes a top portion and a bottom portion opposite to each other, an internal space located between the top portion and the bottom portion, and a first opening communicating with the internal space. The top portion includes multiple through holes. The bottom portion is connected to the heat generating component. The first wing housing is connected to the central housing and includes a first entrance distant from the central housing and communicating with the first opening. The first entrance has a larger dimension than the first opening. An air flow sequentially flows through the first entrance, the first opening, and the internal space and flows out from the through holes.

In an embodiment of the disclosure, the above-mentioned first wing housing includes a diverging area, the first opening is adjacent to a first side of the diverging area, the first entrance is formed on a second side of the diverging area, and the diverging area gradually expands from the first side towards the second side.

In an embodiment of the disclosure, the above-mentioned first wing housing includes a first wing portion and a second wing portion, each of the first wing portion and the second wing portion includes a connection section and an inclined section extending from the connection section in a bent manner, and the inclined section of the first wing portion and the inclined section of the second wing portion are inclined in a direction away from each other.

In an embodiment of the disclosure, the above-mentioned first wing housing includes a first wing portion and a second wing portion, one of the first wing portion and the second wing portion extends parallel to the central housing, the other of the first wing portion and the second wing portion includes a connection section connected to the central housing and an inclined section extending from the connection section in a bent manner, and the inclined section is inclined in a direction away from the central housing.

In an embodiment of the disclosure, the above-mentioned first wing housing includes a first wing portion and a second wing portion, the first wing portion is parallel to the second wing portion, and one of the first wing portion and the second wing portion in a direction on a side away from the first opening has a length greater than the other.

In an embodiment of the disclosure, the above-mentioned heat dissipation structure further includes a second wing housing. The central housing further includes a second opening opposite to the first opening and communicating with the internal space, and the second wing housing is connected to the central housing and includes a second entrance distant from the central housing and communicating with the second opening. The second entrance has a dimension larger than the second opening, and an air flow sequentially flows through the second entrance, the second opening, the internal space and flows out from the through holes.

In an embodiment of the disclosure, the above-mentioned second wing housing includes a diverging area, the second opening is adjacent to a third side of the diverging area, the second entrance is formed on a fourth side of the diverging area, and the diverging area gradually expands from the third side towards the fourth side.

In an embodiment of the disclosure, the above-mentioned second wing housing includes a third wing portion and a fourth wing portion, each of the third wing portion and the fourth wing portion includes a connection section and an inclined section extending from the connection section in a bent manner, and the inclined section of the third wing portion and the inclined section of the fourth wing portion are inclined in a direction away from each other.

In an embodiment of the disclosure, the above-mentioned second wing housing includes a third wing portion and a fourth wing portion, one of the third wing portion and the fourth wing portion extends parallel to the central housing, the other of the third wing portion and the fourth wing portion includes a connection section connected to the central housing and an inclined section extending from the connection section in a bent manner, and the inclined section is inclined in a direction away from the central housing.

In an embodiment of the disclosure, the above-mentioned second wing housing includes a third wing portion and a fourth wing portion, the third wing portion is parallel to the fourth wing portion, and one of the third wing portion and the fourth wing portion in a direction on a side away from the second opening has a length greater than the other.

In an embodiment of the disclosure, the above-mentioned heat dissipation structure further includes at least one heat dissipation fin, and the heat dissipation fin is located in the internal space and disposed on the top portion or/and the bottom portion.

Based on the above, the heat dissipation structure of the disclosure includes a central housing and a first wing housing. The central housing includes a top portion, a bottom portion, an internal space located between the top portion and the bottom portion, and a first opening communicating with the internal space. The top portion includes multiple through holes, and the bottom portion is connected to a heat generating component. The first wing housing is connected to the central housing and includes a first entrance distant from the central housing and communicating with the first opening. The first entrance of the heat dissipation structure has a dimension larger than the first opening, so the pressure of the air flow at the first entrance is greater than the pressure of the air flow at the first opening. The pressure difference accelerates the velocity of the air flow moving towards the central housing, so the heat exchange efficiency is enhanced. In this way, the external air flow sequentially flows through the first entrance, the first opening, and the internal space and flows out from the through holes on the top portion, so as to discharge the heat generated by the heat generating component from the heat dissipation structure. In addition, because the heat dissipation structure improves the heat dissipation efficiency via heat conviction, the heat dissipation structure has good heat dissipation performance. Compared to designs that require configuration of heavy heat dissipation fins for heat dissipation, the structure of the disclosure is lightweight, which can effectively reduce the overall weight of the device.

### BRIEF DESCRIPTION OF THE DRAWINGS

FIG. 1A is a schematic diagram of a heat dissipation structure according to an embodiment of the disclosure.

FIG. 1B is a schematic diagram of the heat dissipation structure of FIG. 1A from another viewing angle.

FIG. 2A is a schematic cross-sectional view of the heat dissipation structure of FIG. 1A.

FIG. 2B is a schematic diagram of a heat dissipation structure according to another embodiment of the disclosure.

FIG. 3 is a cross-sectional view of a heat dissipation structure according to another embodiment of the disclosure.

FIG. 4 is a cross-sectional view of a heat dissipation structure according to another embodiment of the disclosure.

FIG. 5 is a cross-sectional view of a heat dissipation structure according to another embodiment of the disclosure.

FIG. 6 is a cross-sectional view of a heat dissipation structure according to another embodiment of the disclosure.

FIG. 7 is a schematic diagram of a heat dissipation structure according to another embodiment of the disclosure.

### DESCRIPTION OF THE EMBODIMENTS

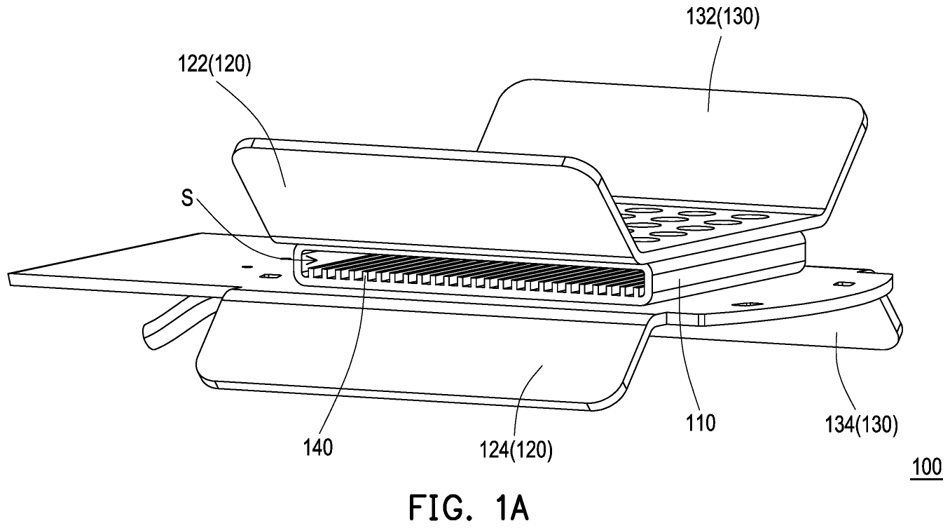

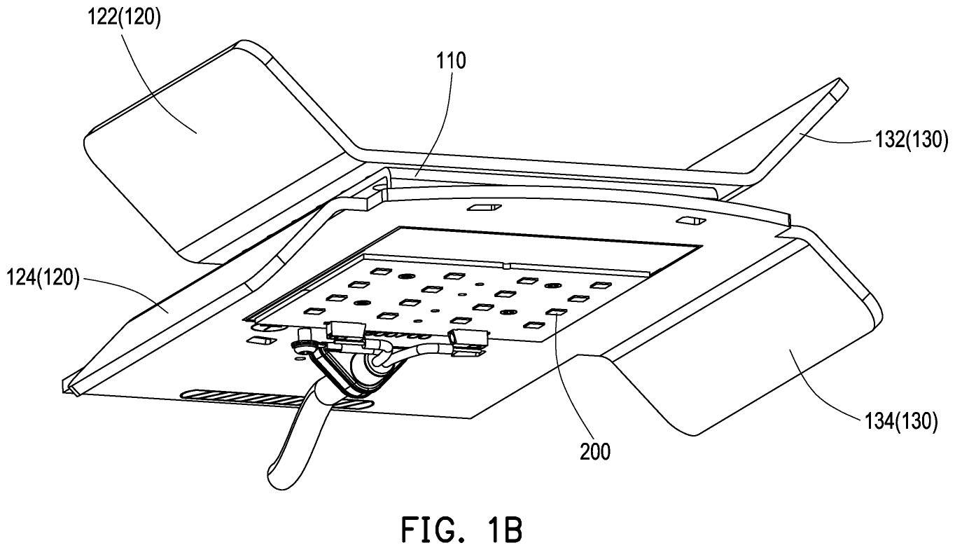

FIG. 1A is a schematic diagram of a heat dissipation structure according to an embodiment of the disclosure. FIG. 1B is a schematic diagram of the heat dissipation structure of FIG. 1A from another viewing angle. Referring to FIGS. 1A and 1B, a heat dissipation structure 100 of the embodiment includes a central housing 110, a first wing housing 120, and a second wing housing 130, and is adapted to dissipate heat from a heat generating component 200 (FIG. 1B), so as to prevent the heat generating component 200 from being damaged or reduced in service life due to high temperature by operation. The heat dissipation structure 100 is, for example, a lamp housing or a lamp holder of a street lamp, and the heat generating component 200 is, for example, a lamp body of a street lamp, but the application field of the heat dissipation structure 100 and the type of the heat dissipation element 200 are not limited thereto.

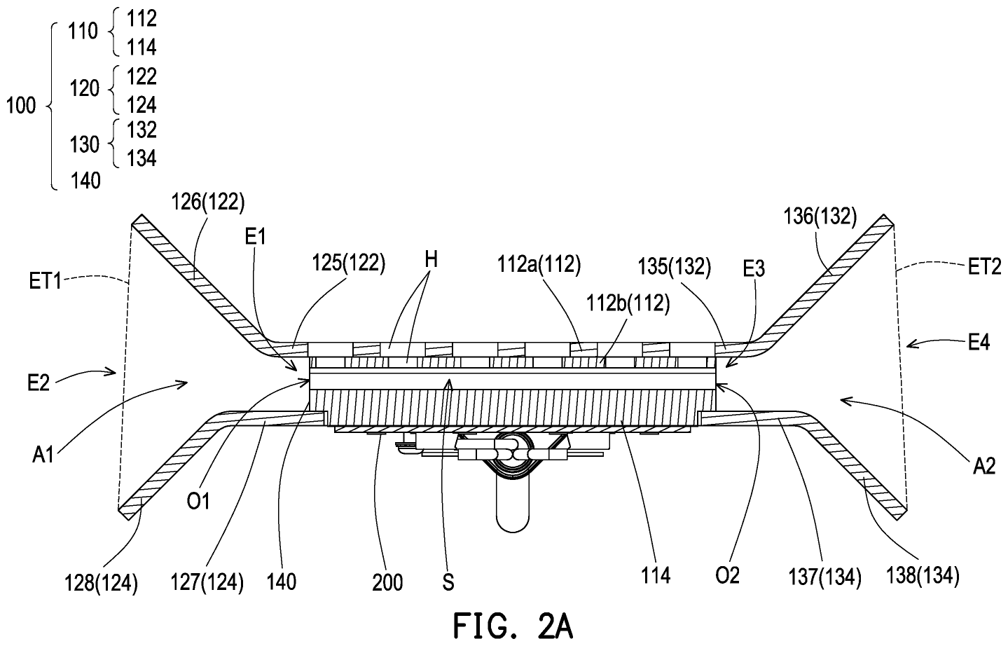

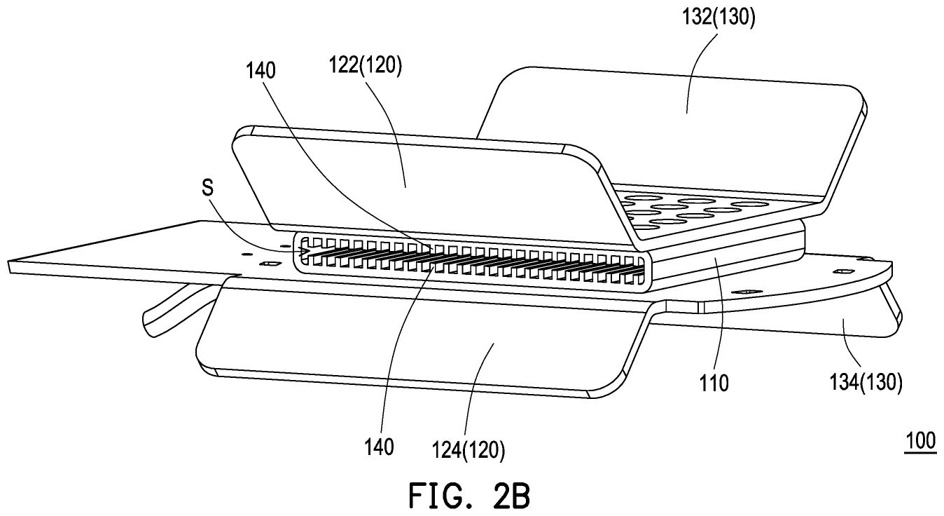

FIG. 2A is a schematic cross-sectional view of the heat dissipation structure of FIG. 1A. Referring to FIG. 2A, the central housing 110 of the heat dissipation structure 100 includes a top portion 112 and a bottom portion 114 opposite to each other, an internal space S between the top portion 112 and the bottom portion 114, a first opening O1 and a second opening O2 communicating with the internal space S. The top portion 112 includes multiple through holes H. The bottom portion 114 is connected to the heat generating component 200, and the heat from the heat generating component 200 may be conducted to the bottom portion 114. The first opening O1 and the second opening O2 are respectively located on opposite sides of the internal space S and are between the top portion 112 and the bottom portion 114.

The first wing housing 120 is connected to the central housing 110, and includes a diverging area A1 and a first entrance ET1 distant from the central housing 110 and communicating with the first opening O1. The first opening O1 is located adjacent to a first side E1 of the diverging area A1, the first entrance ET1 is formed on a second side E2 of the diverging area A1, and the diverging area A1 gradually expands from the first side E1 to the second side E2 so that the dimension of the first entrance ET1 is larger than that of the first opening O1.

Further, the first wing housing 120 includes a first wing portion 122 and a second wing portion 124. The first wing portion 122 includes a connection section 125 connected to the central housing 110 and an inclined section 126 extending from the connection section 125 in a bent manner. The second wing portion 124 includes a connection section 127 connected to the central housing 110 and an inclined section 128 extending from the connection section 127 in a bent manner. The inclined section 126 of the first wing portion 122 and the inclined section 128 of the second wing portion 124 are inclined in a direction away from each other.

On the other hand, similar to the structure and configuration of the first wing housing 120, the second wing housing 130 is connected to the central housing 110, and includes a diverging area A2 and a second entrance ET2 distant from the central housing 110 and communicating with the second opening O2. The second opening O2 is located adjacent to a third side E3 of the diverging area A2, the second entrance ET2 is formed on a fourth side E4 of the diverging area A2, and the diverging area A2 gradually expands from the third side E3 to the fourth side E4 so that the dimension of the second entrance ET2 is larger than that of the second opening O2.

Further, the second wing housing 130 includes a third wing portion 132 and a fourth wing portion 134. The third wing portion 132 includes a connection section 135 connected to the central housing 110 and an inclined section 136 extending from the connection section 135 in a bent manner. The fourth wing portion 134 includes a connection section 137 connected to the central housing 110 and an inclined section 138 extending from the connection section 137 in a bent manner. The inclined section 136 of the third wing portion 132 and the inclined section 138 of the fourth wing portion 134 are inclined in a direction away from each other.

When entering the heat dissipation structure 100 from the second side E2, the air flow sequentially flows through the first entrance ET1, the diverging area A1, the first opening O1, and the internal space S, and flows out from the through holes H. During the air flow movement, since the dimension of the first entrance ET1 is larger than that of the first opening O1, the pressure of the air at the first entrance ET1 is greater than the pressure of the air at the first opening O1. The pressure difference accelerates the velocity of the air flow moving towards the central housing 110 (for example, the velocity of the air at the first opening O1 is greater than the velocity of the air at the first entrance ET1). In this way, when the heat generated by the heat generating component 200 is conducted to the central housing 110, the heat can be carried by the fast air flow entering the internal space S and quickly exit the central housing 110 from the through holes H, thereby achieving a good heat dissipation effect.

Similarly, the air flow also enters the heat dissipation structure 100 from the fourth side ET4 at the same time, that is, the air flow sequentially flows through the second entrance ET2, the diverging area A2, the second opening O2, and the internal space S, and flows out from the through holes H. Since the dimension of the second entrance ET2 is larger than that of the second opening O2, the pressure of the air at the second entrance ET2 is greater than the pressure of the air at the second opening O2. The pressure difference accelerates the velocity of the air flow moving towards the central housing 110 (for example, the velocity of the air at the second opening O2 is greater than the velocity of the air at the second entrance ET2). In this way, the heat dissipation effect similar to the first wing housing 120 as aforementioned can be achieved.

In other embodiments, the heat dissipation structure 100 may include the central housing 110 and only one wing housing (i.e., the first wing housing 120 or the second wing housing 130) Such configuration is also beneficial from utilizing the difference in air pressure to achieve the effect of heat dissipation.

In short, the heat dissipation structure 100 forms a natural air pressure difference by having the dimension of the first entrance ET1 to be larger than that of the first opening O1 (or/and the dimension of the second entrance ET2 to be larger than that of the second opening O2), so that the air flow entering the heat dissipation structure 100 is accelerated, and the heat exchange efficiency between the central housing 110 and the air is enhanced, thereby improving the overall heat dissipation capability. Compared to conventional heat dissipation designs with heavy heat dissipation fins, the heat dissipation structure 100 not only has better heat dissipation performance, but also has a lighter and thinner structure. In addition, under the condition of the same weight, the specific surface area of the heat dissipation structure 100 is larger than the specific surface area of the conventional heat dissipation fins, thereby improving the heat exchange efficiency.

In addition, the top portion 112 of the central housing 110 in the embodiment is a two-layer structure. The top portion 112 includes an upper top layer 112a and a lower top layer 112b, and the through holes H are located in the upper top layer 112a and the lower top layer 112b. The through hole H of the upper top layer 112a communicates with the through hole H of the lower top layer 112b, so that the air in the internal space S is discharged through the through hole H of the upper top layer 112a and the through hole H of the lower top layer 112b.

The upper top layer 112a is, for example, integrally formed with the first wing portion 122 and the third wing portion 132 by aluminum extrusion, and the lower top layer 112b is made by, for example, bending aluminum plate. In other embodiments, the top portion 112 of the central housing 110 may be a single-layer structure connected to the first wing portion 122 and the third wing portion 132. The disclosure does not limit the manufacture and configuration of the central housing 110, the first wing housing 120, and the second wing housing 130.

FIG. 2B is a schematic diagram of a heat dissipation structure according to another embodiment of the disclosure. Referring to FIGS. 1A, 2A, and 2B, the heat dissipation structure 100 may optionally be configured with at least one heat dissipation fin 140. For example, the heat dissipation fin 140 may be located in the internal space S of the central housing 110 and disposed on the top portion 112 (FIG. 2A) or/and the bottom portion 114 (FIG. 2A). By arranging the thin heat dissipation fin 140 inside the central housing 110, the specific surface area of the inner wall of the central housing 110 may be increased, thereby improving the heat exchange efficiency and the heat dissipation capability of the heat dissipation structure 100. As shown in FIG. 2B, the heat dissipation structure 100 may also include two thin heat dissipation fins 140, the two heat dissipation fins 140 are located in the internal space S and respectively disposed on the top portion 112 and the bottom portion 114 to further improve the heat exchange efficiency.

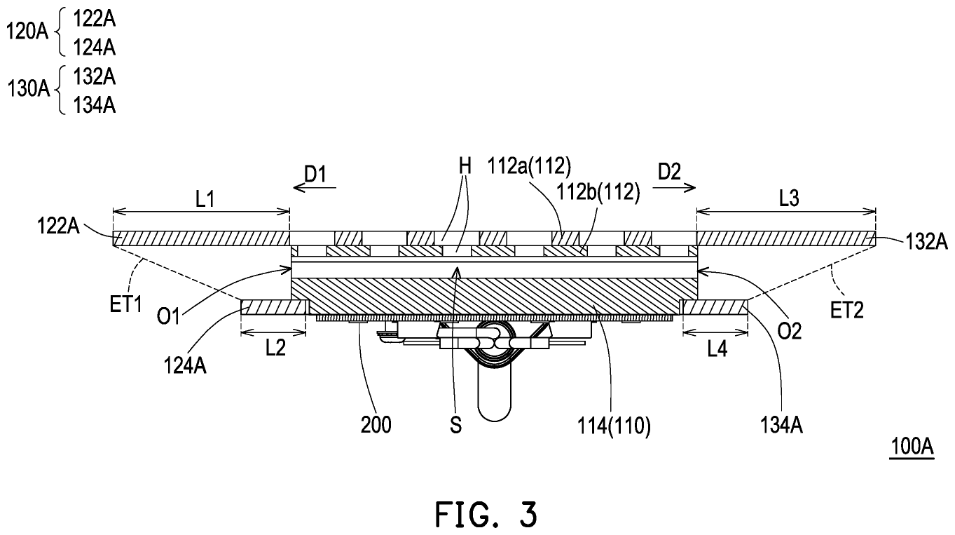

FIG. 3 is a schematic cross-sectional view of a heat dissipation structure according to another embodiment of the disclosure. The difference between the embodiment of FIG. 3 and the embodiment of FIG. 2A is that the two wing portions of a first wing housing 120A of a heat dissipation structure 100A of FIG. 3 are parallel to each other, and the two wing portions of a second wing housing 130A are parallel to each other. Referring to FIG. 3, in detail, a first wing portion 122A of the first wing housing 120A is parallel to a second wing portion 124A, and one of the first wing portion 122A and the second wing portion 124A in a direction D1 on a side away from the first opening O1 has a length L1 greater than a length L2 of the other.

Since the length L1 of the first wing portion 122A is greater than the length L2 of the second wing portion 124A, the dimension of the first entrance ET1 is still larger than that of the first opening O1, so that the pressure of the air at the first entrance ET1 is greater than the pressure of the air at the first opening O1, thereby forming a pressure difference and accelerating the air flow flowing through the heat dissipation structure 100A. Therefore, the heat from the heat generating component 200 can be instantly discharged from the central housing 110 with the air flow to achieve a good heat dissipation effect.

Similarly, a third wing portion 132A of the second wing housing 130A is parallel to a fourth wing portion 134A, and one of the third wing portion 132A and the fourth wing portion 134A in another direction D2 on a side away from the second opening O2 has a length L3 greater than a length L4 of the other.

Since the length L3 of the third wing portion 132A is greater than the length L4 of the fourth wing portion 134A, the dimension of the second entrance ET2 is larger than that of the second opening O2, so that the pressure of the air at the second entrance ET2 is greater than the pressure of the air at the second opening O2, thereby forming a pressure difference. Therefore, the heat dissipation effect similar to the first wing housing 120A as aforementioned can be achieved.

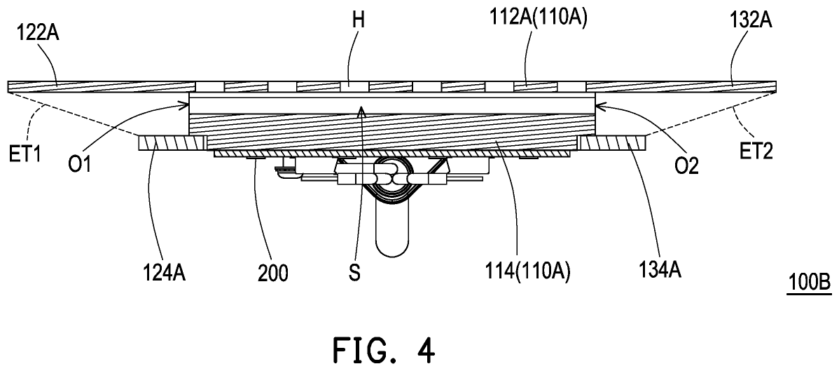

FIG. 4 is a schematic cross-sectional view of a heat dissipation structure according to another embodiment of the disclosure. The difference between the embodiment of FIG. 4 and the embodiment of FIG. 3 lies in that a top portion 112A of a heat dissipation structure 100B of FIG. 4 is a single-layer structure, which can further reduce the weight of the heat dissipation structure 100B. Referring to FIG. 4, the top portion 112A of a central housing 110A, the first wing portion 122A, and the third wing portion 132A in the embodiment are integrally formed, for example, by aluminum extrusion. In other embodiments, the top portion 112A, the first wing portion 122A, and the third wing portion 132A may be separate components assembled together as a combination.

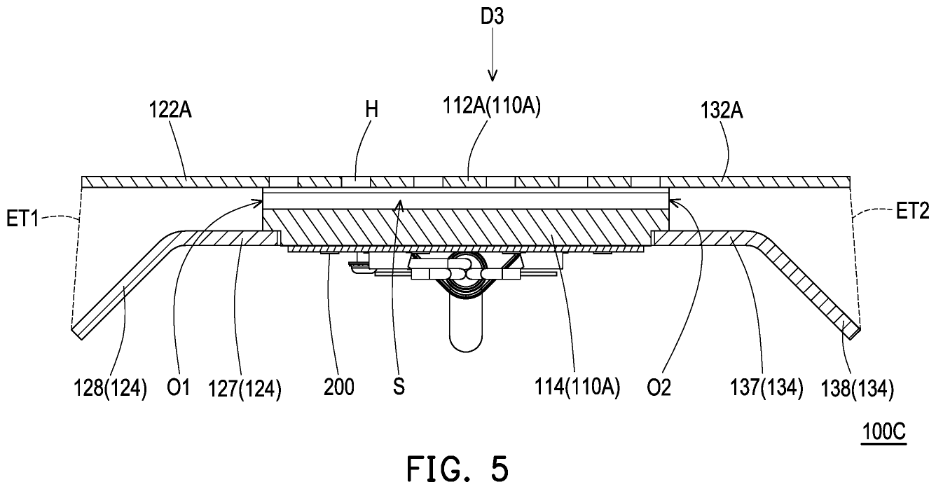

FIG. 5 is a schematic cross-sectional view of a heat dissipation structure according to another embodiment of the disclosure. The difference between the embodiment of FIG. 5 and the embodiment of FIG. 4 lies in that one of the first wing portion 122A and the second wing portion 124 of a heat dissipation structure 100C of FIG. 5 has an inclined section, and one of the third wing portion 132A and the fourth wing portion 134 also has an inclined section.

Referring to FIG. 5, in detail, one of the first wing portion 122A and the second wing portion 124 extends parallel to the central housing 110A, the other of the first wing portion 122A and the second wing portion 124 includes the connection section 127 connected to the central housing 110A and the inclined section 128 extending from the connection section 127 in a bent manner, and the inclined section 128 is inclined in a direction D3 away from the central housing 110A. In the embodiment, the first wing portion 122A extends parallel to the top portion 112A of a central housing 110A, and the second wing portion 124 has the connection section 127 connected to the bottom portion 114 of the central housing 110A and the inclined section 128.

Therefore, the dimension of the first entrance ET1 is larger than that of the first opening O1, so that the pressure of the air at the first entrance ET1 is greater than the pressure of the air at the first opening O1, thereby forming a pressure difference and accelerating the air flow flowing through a heat dissipation structure 100C. Thus, the heat of the heat generating component 200 can be instantly discharged from the central housing 110A with the air flow to achieve a good heat dissipation effect.

Similarly, one of the third wing portion 132A and the fourth wing portion 134 extends parallel to the central housing 110A, the other of the third wing portion 132A and the fourth wing portion 134 includes the connection section 137 connected to the central housing 110A and the inclined section 138 extending from the connection section 137 in a bent manner, and the inclined section 138 is inclined in the direction D3 away from the central housing 110A. In the embodiment, the third wing portion 132A extends parallel to the top portion 112A of the central housing 110A, and the fourth wing portion 134 has the connection section 137 and the inclined section 138 connected to the bottom portion 114 of the central housing 110A. Therefore, the dimension of the second entrance ET2 is larger than that of the second opening O2, so that the pressure of the air at the second entrance ET2 is greater than the pressure of the air at the second opening O2, thereby forming a pressure difference. Thus, the heat dissipation effect similar to the first wing portion 122A and the second wing portion 124 as aforementioned can be achieved.

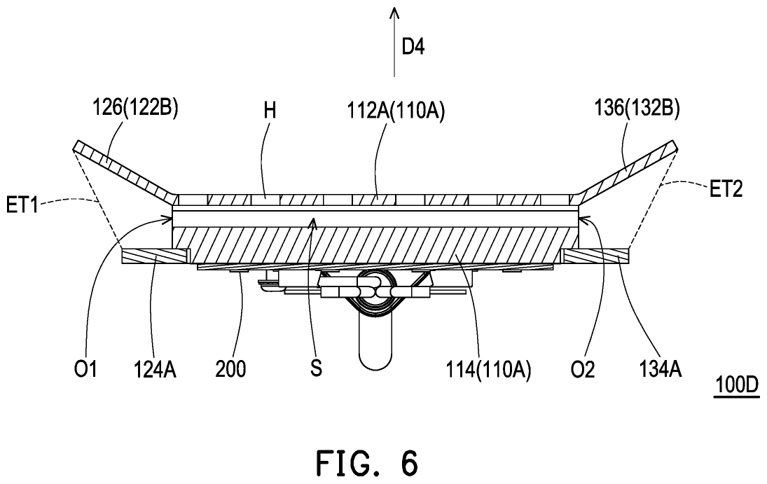

FIG. 6 is a schematic cross-sectional view of a heat dissipation structure according to another embodiment of the disclosure. The difference between the embodiment of FIG. 6 and the embodiment of FIG. 5 lies in that a first wing portion 122B of a heat dissipation structure 100D of FIG. 6 has the inclined section 126, and a third wing portion 132B has the inclined section 136.

Referring to FIG. 6, in detail, the first wing portion 122B includes the inclined section 126 extending from the central housing 110A in a bent manner, the second wing portion 124A extends parallel to the bottom portion 114, and the inclined section 126 of the first wing portion 122B is inclined in a direction D4 away from the second wing portion 124A. Therefore, the dimension of the first entrance ET1 is larger than that of the first opening O1, so that the pressure of the air at the first entrance ET1 is greater than the pressure of the air at the first opening O1, thereby forming a pressure difference and accelerating the air flow flowing through the heat dissipation structure 100D. Thus, the heat of the heat generating component 200 can be instantly discharged from the central housing 110A with the air flow to achieve a good heat dissipation effect.

Similarly, the third wing portion 132B includes the inclined section 136 extending from the central housing 110A in a bent manner, the fourth wing portion 134A extends parallel to the bottom portion 114, and the inclined section 136 of the third wing portion 132B is inclined in the direction D4 away from the fourth wing portion 134A. Therefore, the dimension of the second entrance ET2 is larger than that of the second opening O2, so that the pressure of the air at the second entrance ET2 is greater than the pressure of the air at the second opening O2, thereby forming a pressure difference and achieving the heat dissipation effect similar to the first wing portion 122B and the second wing portion 124A as aforementioned.

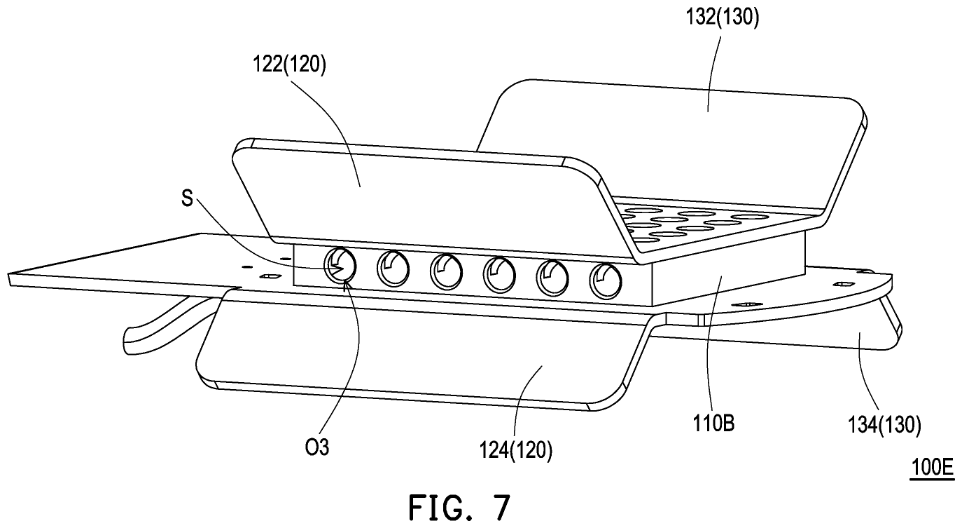

FIG. 7 is a schematic diagram of a heat dissipation structure according to another embodiment of the disclosure. The difference between the embodiment of FIG. 7 and the embodiment of FIG. 1A lies in that the shape of a first opening O3 and the second opening (not shown due to viewing angle) opposite to the first opening O3 of a central housing 110B of a heat dissipation structure 100E of FIG. 7 are circular. Certainly, the shape of the first opening O3 and the second opening may also be square, rhombus, trapezoid or heart-shaped, etc., and the disclosure is not limited thereto.

In addition, although in the above-mentioned embodiments of the disclosure, the configurations of the first wing portion and the third wing portion are illustrated as the same, and the configurations of the second wing portion and the fourth wing portion are illustrated as the same, those skilled in the disclosure should understand that in other embodiments, the configuration of the first wing portion may be different from the third wing portion, and the configuration of the second wing portion may be different from the fourth wing portion.

In summary, the heat dissipation structure of the disclosure includes a central housing, a first wing housing, and a second wing housing. The central housing includes a top portion, a bottom portion, an internal space located between the top portion and the bottom portion, and a first opening and a second opening communicating with the internal space. The top portion includes multiple through holes, and the bottom portion is connected to a heat generating component. The first wing housing and the second wing housing are connected to the central housing, and respectively include a first entrance distant from the central housing and communicable with the first opening, and a second entrance distant from the central housing and communicable with the second opening. The first entrance of the heat dissipation structure has a dimension larger than that of the first opening, and the second entrance has a dimension larger than that of the second opening. Thus, the pressure of the air flow at the first entrance is greater than the pressure of the air flow at the first opening, and the pressure of the air flow at the second entrance is greater than the pressure of the air flow at the second opening, thereby forming a pressure difference on both sides of the central housing. Therefore, the velocity of the air flow moving towards the central housing is accelerated and the heat exchange efficiency is enhanced, and the heat dissipation effect is improved.

In this way, the external air flow may sequentially flow through the first entrance, the first opening, and the internal space, or sequentially flow through the second entrance, the second opening, and the internal space, and flow out from the through holes on the top portion, so as to discharge the heat generated by the heat generating component from the heat dissipation structure. In addition, because heat dissipation efficiency of the heat dissipation structure is improved via heat convection, the heat dissipation structure has good heat dissipation performance. Moreover, the disclosure has light structure and does not require heavy heat dissipation fins as in conventional designs that merely relies on heat dissipation fins to dissipate heat, and can effectively reduce the overall weight.

Although the disclosure has been described with reference to the above embodiments, the described embodiments are not intended to limit the disclosure. Without departing from the spirit and the scope of the disclosure, various changes, modifications, and combinations made to the embodiments are covered by the scope of the disclosure.

What is claimed is:

1. A heat dissipation structure, adapted to dissipate heat from a heat generating component, the heat dissipation structure comprising:
a central housing, comprising a top portion and a bottom portion opposite to each other, an internal space located between the top portion and the bottom portion, and a first opening communicating with the internal space, wherein the top portion comprises a plurality of through holes, and the bottom portion is connected to the heat generating component; and
a first wing housing, connected to the central housing and comprising a first entrance distant from the central housing and communicating with the first opening,
wherein, the first entrance has a larger dimension than the first opening, and an air flow sequentially flowing through the first entrance, the first opening, the internal space and flowing out from the through holes.

2. The heat dissipation structure according to claim 1, wherein the first wing housing comprises a diverging area, the first opening is adjacent to a first side of the diverging area, the first entrance is formed on a second side of the diverging area, and the diverging area gradually expands from the first side towards the second side.

3. The heat dissipation structure according to claim 1, wherein the first wing housing comprises a first wing portion and a second wing portion, each of the first wing portion and the second wing portion comprises a connection section connected to the central housing and an inclined section extending from the connection section in a bent manner, and the inclined section of the first wing portion and the inclined section of the second wing portion are inclined in a direction away from each other.

4. The heat dissipation structure according to claim 1, wherein the first wing housing comprises a first wing portion and a second wing portion, one of the first wing portion and the second wing portion extends parallel to the central housing, the other of the first wing portion and the second wing portion comprises a connection section connected to the central housing and an inclined section extending from the connection section in a bent manner, and the inclined section is inclined in a direction away from the central housing.

5. The heat dissipation structure according to claim 1, wherein the first wing housing comprises a first wing portion and a second wing portion, the first wing portion is parallel to the second wing portion, and one of the first wing portion and the second wing portion in a direction on a side away from the first opening has a length greater than the other.

6. The heat dissipation structure according to claim 1, further comprising a second wing housing, wherein the central housing further comprises a second opening opposite to the first opening and communicating with the internal space, the second wing housing is connected to the central housing and comprises a second entrance distant from the central housing and communicating with the second opening, the second entrance has a dimension larger than the second opening, and an air flow sequentially flows through the second entrance, the second opening, and the internal space and flows out from the through holes.

7. The heat dissipation structure according to claim 6, wherein the second wing housing comprises a diverging area, the second opening is adjacent to a third side of the diverging area, the second entrance is formed on a fourth side of the diverging area, and the diverging area gradually expands from the third side towards the fourth side.

8. The heat dissipation structure according to claim 6, wherein the second wing housing comprises a third wing portion and a fourth wing portion, each of the third wing portion and the fourth wing portion comprises a connection section connected to the central housing and an inclined section extending from the connection section in a bent manner, and the inclined section of the third wing portion and the inclined section of the fourth wing portion are inclined in a direction away from each other.

9. The heat dissipation structure according to claim 6, wherein the second wing housing comprises a third wing portion and a fourth wing portion, one of the third wing portion and the fourth wing portion extends parallel to the central housing, the other of the third wing portion and the fourth wing portion comprises a connection section connected to the central housing and an inclined section extending from the connection section in a bent manner, and the inclined section is inclined in a direction away from the central housing.

10. The heat dissipation structure according to claim 6, wherein the second wing housing comprises a third wing portion and a fourth wing portion, the third wing portion is parallel to the fourth wing portion, and one of the third wing portion and the fourth wing portion in a direction on a side away from the second opening has a length greater than the other.

11. The heat dissipation structure according to claim 1, further comprising at least one heat dissipation fin, wherein the heat dissipation fin is located in the internal space and disposed on the top portion or/and the bottom portion.
